(19) United States
(12) Patent Application Publication
(10) Pub. No.: US 2011/0265720 A1
(43) Pub. Date: Nov. 3, 2011

(54) GAS DEPOSITION REACTOR

(75) Inventors: Jarmo Maula, Espoo (FI); Hannu Leskinen, Espoo (FI); Kari Harkonen, Kauniainen (FI)

(73) Assignee: BENEQ OY, Vantaa (FI)

(21) Appl. No.: 13/143,306

(22) PCT Filed: Feb. 11, 2010
(86) PCT No.: PCT/FI2010/050088

§ 371 Date: Jul. 5, 2011

(30) Foreign Application Priority Data
Feb. 13, 2009 (FI) 20095139

(51) Int. Cl. C23C 16/46

(52) U.S. Cl. 118/719

(57) ABSTRACT

A reactor is provided for a gas deposition method, in which method the surface of a substrate is subjected to alternate starting material surface reactions. The reactor includes a first chamber, a second chamber mounted inside the first chamber, and heating means for heating the first chamber. The reactor also includes one or more heat transfer elements for equalising temperature differences inside the first chamber.

### BACKGROUND OF THE INVENTION

The invention relates to a gas deposition reactor for gas deposition methods and especially to a gas deposition reactor for a gas deposition method in which the surface of the substrate is subjected to alternate starting material surface reactions, the reactor comprising a first chamber, a second chamber mounted inside the first chamber, and heating means for heating the first chamber.

Gas deposition methods generally use a gas deposition reactor that comprises a first chamber and a second chamber provided inside thereof. A pressure chamber, such as a low-pressure chamber that isolates the system from the environment, is generally used as the first chamber. Instead of a low-pressure chamber, it is also possible to use an over-pressure chamber or a chamber with substantially normal air pressure. A pressure of approximately 10 to 1000 Pa is typically used in the low-pressure chamber. The dimensions of the first chamber structure are generally relatively large in view of natural convection manifestation, even at lower pressures. This natural convection may cause thermal imbalance inside the first chamber. A separate second chamber, such as a reaction chamber, inside which the substrates to be treated are placed, is generally positioned inside the first chamber. Natural convection may also cause temperature differences inside the second chamber, especially when it becomes large in size. The heating of the second chamber and thus also of the substrates inside it is conventionally done by means of heating means provided on the walls of the second chamber or by heating the walls of the second chamber indirectly with radiation, for instance, when the heating means are mounted on the walls of the first chamber.

For an efficient production it is necessary that the gas deposition equipment produces in consecutively repeating process runs and within one and the same process run coatings, deposition layers or doping layers with uniform properties. In other words, it is appropriate for the products treated in different batches or in the same batch to have uniform properties, whereby the process parameters of the gas deposition method must be uniform in consecutive process runs and within the same process run at different locations of the reactor. Thus, the critical process parameters must be constant in different process runs and at different points of the reactor during one process run. One of these critical process parameters is the temperature of the substrate (surface being coated) during the deposition process. The deposition rate of the coating is generally dependent on the temperature of the substrate such that deviations from the temperature of the substrate in consecutive process runs or within the same process run lead to deviations of the coating properties from the required values.

In a gas deposition method in which the surface of the substrate is subjected to consecutive surface reactions of starting materials, batch processing is advantageous, because the heating and coating/doping of the substrates takes a lot of time, whereby the treatment of several substrates side by side provides economical advantages. In addition, a gas deposition method, such as ALD (atomic layer deposition), is especially suitable to be done as batch processing, because ALD provides extremely good uniform coating properties and allows a great deal of freedom in the positioning of the parts to be coated inside the second chamber. When using large reactors or high reactors in which large pieces are processed or at one go batches that comprise a large number of substrates placed on top of each other, for example, the dimensions of the reactors cause temperature differences inside the first chamber. These temperature differences often result from the structures of the first chamber, the second chamber and other parts, which may generate and control heat flows inside the first chamber. For instance, in some parts of the first chamber, heat flows may flow toward the second chamber, and in other parts away from the second chamber. Thus, the heat flows cause temperature differences around the second chamber. The highest temperatures are then often in the top part of the reactor or first chamber and the lowest temperatures in the bottom part. A further factor affecting this may be natural convection that may cause temperature differences inside the first chamber even though the heating effect was distributed evenly in the elevation of the first chamber.

In prior-art solutions, attempts have been made to equalise the temperature differences inside a furnace or heated reactor by using forced convection. However, gas deposition methods are sensitive to flows and the use of a blower or a corresponding forced convection method causes unwanted interference to the gas flows. External forced convection of the second chamber is a possible solution, but the particle movement caused by the flows is harmful and forced convection is not generally used in coating devices. In addition, natural convection may also cause temperature differences inside the second chamber, especially when it becomes large in size. In batch processing in which several substrates are set on top of each other on a support rack, the substrates on the top part of the support rack maybe at a different temperature than those on the bottom part owing to the temperature differences described above. In the prior art, this problem has been solved by placing heaters or corresponding heating means inside the support rack, between superposed substrates, for example. The above-mentioned use of separate heaters also makes it possible to process large or high substrates. The use of separate heaters in a support rack or other substrate support structures or in the second chamber makes the equipment unnecessarily complex, because the heaters need to be protected so that deposition layers do not form on them during the performance of the gas deposition method.

### BRIEF DESCRIPTION OF THE INVENTION

It is, thus, an object of the invention to develop a gas deposition reactor for a gas deposition method in such a manner that the above-mentioned problems are solved. The object of the invention is achieved with a gas deposition reactor that is characterised in that the reactor also comprises one or more heat transfer elements made of heat conducting material to equalise and/or adjust temperature differences inside the first chamber.

Preferred embodiments of the invention are set forth in the dependent claims.

The invention is based on positioning in the space between the inner surface of the first chamber and the outer surface of the second chamber of the gas deposition reactor at least one heat transfer element that is made of heat conducting material. The heat transfer element may be a separate heat transfer piece that is positioned in the space between the first and second chambers in such a manner that it transfers heat away from inside the first chamber or in such a manner that it transfers heat through conduction inside the first chamber from hotter zones to cooler zones, thus equalising temperature differences inside the first chamber. Alternatively, the heat transfer element may be provided as an at least partial lining of the inner surface of the first chamber or a lining of the outer surface of the second chamber, whereby it is correspondingly capable of equalising temperature differences inside the first chamber or around the second chamber.

This type of heat transfer element is preferably a static and passive element that is capable of transferring heat and equalising temperature differences inside the first chamber and temperatures in the second chamber even without feedback from the processed substrates and without being subjected to the starting materials or other gaseous substances fed into the second chamber. The solution of the present invention also provides the advantage that it is a simple structure and easy to implement during the manufacturing of new gas deposition reactors and to install in existing gas deposition reactors.

### BRIEF DESCRIPTION OF FIGURES

The invention will now be described in greater detail by means of preferred embodiments and with reference to the attached drawings, in which

FIG. 1 is a schematic view of an embodiment of the invention, in which a separate heat transfer element is installed in the top part of the first chamber;

FIG. 2 is a schematic view of a second embodiment of the invention, in which a heat transfer element is provided as a lining of the inner surface of the first chamber; and

FIG. 3 is a schematic view of a third embodiment of the invention, in which a heat transfer element is provided as a lining of the outer surface of the second chamber.

### DETAILED DESCRIPTION OF THE INVENTION

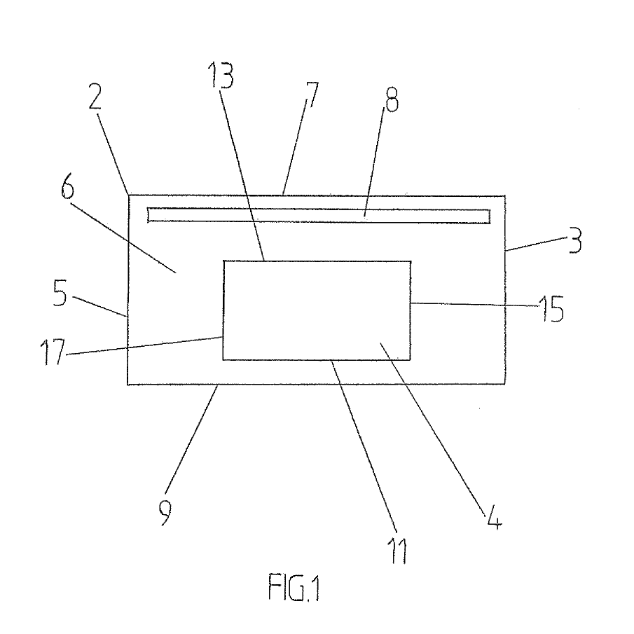

FIG. 1 shows an embodiment of a gas deposition chamber according to the present invention. According to FIG. 1, the gas deposition reactor comprises a first chamber 2, which may be a low-pressure chamber, over-pressure chamber or a pressure chamber with a substantially normal air pressure (NTP: 1 bar, 0° C.). Low pressure refers herein to a low pressure in relation to NTP conditions, and over-pressure refers to an over-pressure in relation to NTP conditions. The first chamber 2 isolates the system from the environment. A pressure of approximately 10 to 1000 is typically used in the low-pressure chamber. The low-pressure chamber may be any prior-art low-pressure chamber or some other corresponding low-pressure chamber that is used in gas deposition reactors. Alternatively, the low-pressure chamber is replaced with an over-pressure chamber or some other corresponding chamber. The gas deposition reactors according to the present invention are intended for use especially in gas deposition methods in which the surface of a substrate is subjected to alternate surface reactions of starting materials. Gas deposition methods of this type include ALD (atomic layer deposition) and ALE (atomic layer epitaxy) and the like. In these and corresponding methods, surface deposition is based on reactions controlled by the surface, which provides uniform deposition on all surfaces of the substrate. In gas deposition reactors of this type, temperature is one of the critical process parameters, because the deposition rate on the surface of the substrate depends on temperature. A substrate refers herein to any single piece, product or the like or a group or series thereof processed in a gas deposition reactor and treated simultaneously in a coating operation.

As shown in FIG. 1, a separate second chamber 4, that is, a reaction chamber or coating chamber inside which the substrates are placed for processing, is further positioned inside the first chamber 2. The second chamber 4 may be any reaction chamber according to the prior art or any corresponding reaction chamber that is arranged to be positioned inside the first chamber 2. The gas deposition reactor also comprises heating means (not shown), with which the inside of the first chamber 2 is heated. The heating means are provided to heat the second chamber 4. In indirect heating of the second chamber 4, the walls of the second chamber 4 are heated indirectly by means of thermal radiation or gas heat conduction, for instance. In indirect heating of the second chamber 4, the heating means may be installed for instance on the side, end, top or bottom walls of the first chamber 2, from which heat transfers by radiation or gas to heat the second chamber 4. The heating means may be electrical resistors, for example. In addition, the heating means are preferably positioned, installed and implemented such that with them an as even temperature distribution as possible is achieved inside the second chamber 4, that is, temperature differences inside the second chamber 4 and around it are as small as possible. However, the space 6 between the inner walls of the first chamber 2 and the outer walls of the second chamber 4 easily causes temperature differences inside the first chamber 2 and, thus, also inside the second chamber 4. These temperature differences often result from the structures of the first chamber 2, the second chamber 4 and other parts, which may generate and control heat flows inside the first chamber 2. Heat flows around the second chamber 4 may then be unevenly distributed in such a manner that at some points, the heat flows proceed toward the second chamber 4 and in other parts away from the second chamber 4. In such a case, temperature differences are created between different points of the second chamber 4. Thus, an object of the present invention is to equalise these temperature differences in a simple and efficient manner.

According to the present invention, the equalising of the temperature differences described above is implemented by means of a heat transfer element 8. In the embodiment of FIG. 1, a separate heat transfer element 8 is positioned in the top part of the first chamber 2 in the space between the first chamber 2 and second chamber 4. According to what is stated above, the temperature distribution in the first chamber 2 of the gas deposition reactor is typically such that the top part of the first chamber 2 has a higher temperature than the bottom part. In the embodiment of FIG. 1, the heating means are typically provided on the side walls 7, 9 and/or top or bottom walls of the first chamber 2 and/or on the casing of the cylindrical first chamber 2 in such a manner that the thermal energy directed to the second chamber 4 is preferably substantially equal in every direction. Alternatively, the heating means are provided in some other manner such that heat may be brought inside the first chamber 2 through the side walls 7, 9 and/or top or bottom walls and/or the casing of the cylindrical first chamber 2. In such a solution, a loading hatch and a maintenance hatch, respectively, are typically provided on the face sides 3, 5 of the second chamber 4. However, lower-temperature zones are often formed in the vicinity of the face sides 3, 5. Thus, in the solution of FIG. 1, a heat transfer element 8 is positioned in the top part of the first chamber 2 where higher temperatures prevail. The heat transfer element 8 is preferably elongated and extends horizontally preferably close to the face sides 3, 5 of the first chamber 2. Thus, the heat transfer element 8 is capable of transferring heat from the top part of the first chamber 2 to the lower-temperature zones close to the face sides 3, 5. The heat transfer element 8 then equalises the temperature differences inside the first chamber 2 by removing thermal energy from the top part of the first chamber 2.

In an alternative solution, a separate heat transfer element 8 may be arranged in such a manner that it is also capable of transferring heat away from the inside of the first chamber 2. The heat transfer element 8 may then be connectable to the face sides 3, 5 of the first chamber 2 in such a manner that thermal energy is transferred from the heat transfer element 8 and on out from the first chamber 2. The temperature of the element 8 may be measured and adjusted by using active cooling, for instance, in the part that brings thermal energy out of the first chamber 2. In another solution, if for instance the one or both of the face sides 3, 5 of the first chamber 2 are equipped with heating means or heat is transferred otherwise through them to the first chamber 2, a separate heat transfer element 8 may be positioned in the space 6 between the first chamber 2 and second chamber 4 to extend substantially between the top and bottom parts of the first chamber 2. There may be one or more heat transfer elements 8 and they may extend either substantially perpendicularly or at an angle to the vertical direction. It is then possible to transfer heat from the top part of the first chamber 2, where a higher temperature prevails, to the bottom part of the first chamber 2, where a lower temperature prevails. The heat transfer elements 8 may be plate-like, rod-like or other corresponding structures suitable for heat transfer. According to this embodiment, the heat transfer elements 8 are positioned inside the first chamber 2 as separate pieces that are installed in the space 6 between the inner surface of the first chamber 2 and outer surface of the second chamber 4 at a distance from the inner surface of the first chamber 2 and outer surface of the second chamber 4.

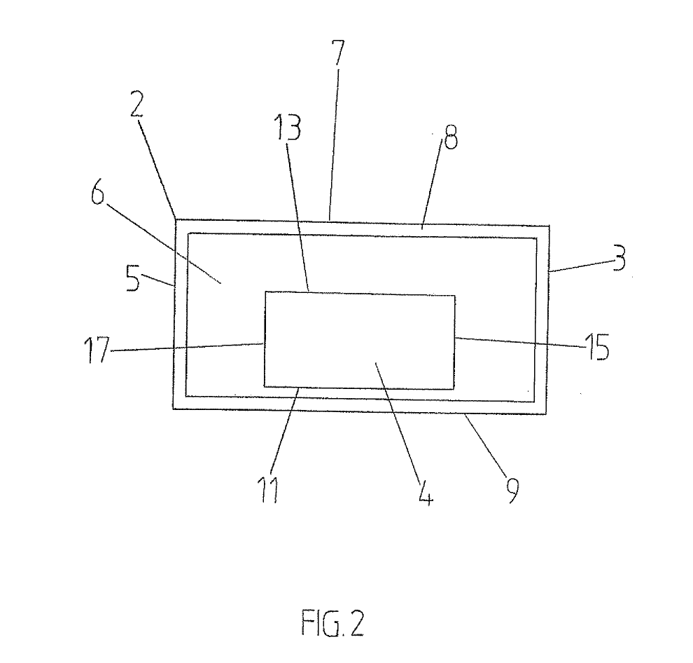

FIG. 2 shows another embodiment of the present invention. In this embodiment, the inner surface of the first chamber 2 is lined with a heat transfer element 8. Even though FIG. 2 shows that the inner surface of the first chamber 2 is lined entirely with a heat transfer element 8, the lining may also be done in such a manner that just a part of the inner surface of the first chamber 2 is lined with a heat transfer element 8 or several heat transfer elements 8. Thus, for instance the face sides 3, 5 of the first chamber 2 may on the inside of the first chamber 2 be lined with heat transfer elements 8 or alternatively only the top side 7 or bottom side 9 of the first chamber 2 may be lined with a heat transfer element 8. In other words, in this embodiment the inner surface of the first chamber 2 is entirely or in any part lined with a heat transfer element 8 that equalises the temperature differences inside the first chamber 2 by conducting heat from the higher-temperature zones to the lower-temperature zones or away from the inside of the first chamber 2. In this embodiment of FIG. 2, the heat transfer element 8 may be a heat transfer plate, for instance, that is installed on the inner surface of the first chamber 2. Alternatively, it is possible to use as heat transfer elements 8 several rod-like, riblike or corresponding pieces that are installed on the inner surface of the first chamber 2. These heat transfer elements 8 may uniformly cover the inner surface of the first chamber 2 or they may be installed side by side at a distance from each other. Thus, the heat transfer element 8 equalises the temperature differences inside the first chamber 2 by transferring heat through conduction from the hotter zones to the cooler ones. Alternatively, the heat transfer element 8 is arranged to transfer heat by conduction away from the first chamber 2 and especially from the hotter zones of the first chamber 2. In this embodiment, the heat transfer elements 8 are also capable of serving as radiation heat sources, if the heating means are provided close to the heating means.

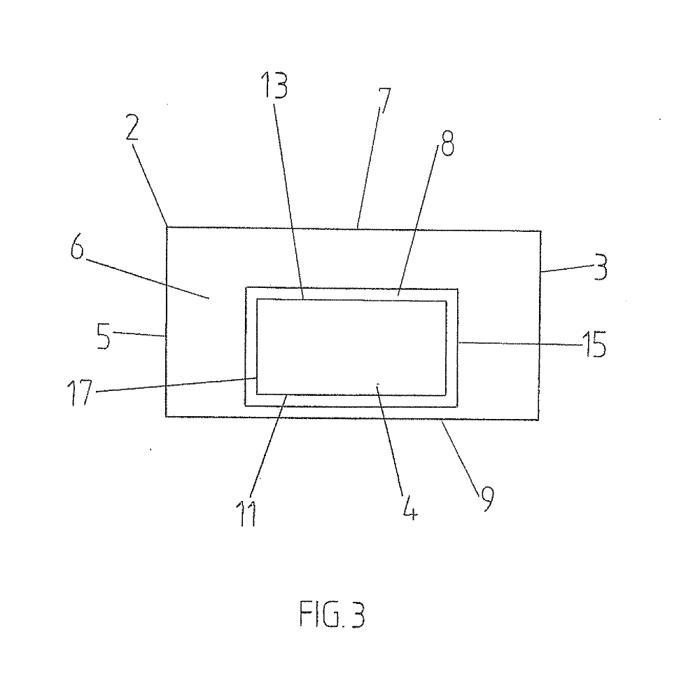

FIG. 3 shows yet another embodiment of the present invention. In this embodiment, the outer surface of the second chamber 4 is lined with a heat transfer element 8 or several heat transfer elements 8. Even though FIG. 3 shows that the outer surface of the second chamber 4 is lined entirely with a heat transfer element 8, the lining may also be done in such a manner that just a part of the outer surface of the second chamber 4 is lined with a heat transfer element 8 or several heat transfer elements 8. Thus, for instance the face sides 15, 17 or top and/or bottom side 13, 11 of the second chamber 4 may on the outside of the second chamber 4 be lined with heat transfer elements 8. In other words, in this embodiment the outer surface of the second chamber 4 is entirely or in any part lined with a heat transfer element 8 that equalises the temperature differences inside the first chamber 2 and/or on the outer surface of the second chamber 4 by conducting heat from the higher-temperature zones to the lower-temperature zones or away from the inside of the second chamber 4. In this embodiment of FIG. 3, the heat transfer element 8 may be a heat transfer plate, for instance, that is installed on the outer surface of the second chamber 4. Alternatively, it is possible to use as heat transfer elements 8 several rod-like, rib-like or corresponding pieces that are installed on the outer surface of the second chamber 4. These heat transfer elements 8 may uniformly cover the outer surface of the second chamber 4 or they may be installed side by side at a distance from each other. Heat transfer elements 8 installed on the outer surface of the second chamber 4 are advantageous, because they are capable of efficiently equalising the heat power directed to the second chamber 4. In other words, heat transfer elements 8 provided on the outer surface of the second chamber 4 equalise by conduction the temperature of the second chamber 4.

The heat transfer arrangement of the invention makes it possible to equalise temperature differences in a low-pressure chamber 2 and thus also to equalise the heat power directed to the reaction chamber at different points of the first chamber 2 and second chamber 4 in a simple manner. In a preferred embodiment the heat transfer elements 8 are passive and static pieces. Alternatively, it is, however, possible to connect the heat transfer element 8 to a thermal element with which the temperature of the heat transfer element 8 may be adjusted. The heat transfer element 8 may then be operationally connected to the heating means of the reactor to adjust the temperature of the heat trans-fer element, or the heat transfer element may be operationally connected to the heating means of the reactor to adjust the temperature of the first chamber 2. Further, a feedback coupling may be provided that utilises values obtained from temperature measurements of the second chamber 4, first chamber 2, or substrates to control the temperature of the heat transfer element 8 or the thermal element. The heat transfer element 8 is preferably made of aluminium or some other material having good heat conductivity, such as copper, beryllium, molybdenum, zirconium, wolfram, zinc, or compounds thereof. The heat transfer element 8 is preferably formed in such a manner that it has a sufficiently large surface area and mass for effective heat transfer.

It is obvious to a person skilled in the art that as technology advances, the basic idea of the invention may be implemented in many different ways. The invention and its embodiments are thus not restricted to the examples described above, but may vary within the scope of the claims.

1. A gas deposition reactor for a gas deposition method in which the surface of a substrate is subjected to alternate starting material mounted inside the first chamber, and heating means for indirectly heating the second chamber, wherein the gas deposition reactor also comprises one or more heat transfer elements made of heat conducting material provided between the inner surface of the first chamber and the outer surface of the second chamber for equalising and/or adjusting temperature differences inside the first chamber.

2. A gas deposition reactor as claimed in claim 1, wherein the heat transfer element is made of a material that conducts heat well to equalise temperature differences inside the first chamber through heat conduction.

3. A gas deposition reactor as claimed in claim 1, wherein in that the heat transfer element is positioned in the space between the first chamber and the second chamber inside it.

4. A gas deposition reactor as claimed in claim 1, wherein the heat transfer element is positioned between heating means and the second chamber.

5. A gas deposition reactor as claimed in claim 1, wherein the heat transfer element is installed on the inner surface of the first chamber or the outer surface the second chamber.

6. A gas deposition reactor as claimed in claim 1, wherein the heat transfer element is arranged to transfer heat inside the first chamber from a hot zone to a cooler zone or away from the inside of the first chamber.

7. A gas deposition reactor as claimed in claim 6, wherein the heat transfer element is arranged to transfer heat away from the top part of the first chamber.

8. A gas deposition reactor as claimed in claim 6, wherein the heat transfer element is arranged to extend substantially horizontally in the top part of the first chamber to transfer heat in the top part of the first chamber toward the end walls of the first chamber or away from the inside of the first chamber.

9. A gas deposition reactor as claimed in claim 1, wherein the heat transfer element is arranged to transfer heat in a direction opposite to natural convection.

10. A gas deposition reactor as claimed in claim 9, wherein the heat transfer element is arranged to extend at least partially perpendicularly or at an angle to the vertical direction inside the first chamber to transfer heat from the top part of the first chamber to the bottom part of the first chamber or away from the inside of the first chamber.

11. A gas deposition reactor as claimed in claim 1, wherein the heat transfer element is formed as a lining provided on the inner surface of the first chamber which covers at least part of the inner surface of the first chamber.

12. A gas deposition reactor as claimed in claim 1, wherein the heat transfer element is formed as a lining provided on the outer surface of the second chamber which covers at least part of the outer surface of the second chamber.

13. A gas deposition reactor as claimed in claim 1, wherein the heat transfer element is provided structurally by making the structure of the second chamber and/or the first chamber substantially thicker than required by their function.

14. A gas deposition reactor as claimed in claim 1, wherein the heat transfer element is a passive heat transfer element.

15. A gas deposition reactor as claimed in claim 1, wherein a thermal element is connected to the heat transfer element for adjusting the temperature of the heat transfer element.

16. A gas deposition reactor as claimed in claim 14, wherein the heat transfer element is operationally connected to the heating means of the reactor to adjust the temperature of the heat transfer element or the heat transfer element is operationally connected to the heating means of the gas deposition reactor to adjust the temperature of the first chamber and/or the second chamber.

17. A gas deposition reactor as claimed in claim 15, wherein the thermal element comprises a feedback coupling in which the temperature of the heat transfer element is adjusted according to the temperature of the second chamber, first chamber or substrates.

18. A gas deposition reactor as claimed in claim 1, wherein the heat transfer element is made of aluminium, copper, beryllium, molybdenum, zirconium, wolfram, zinc, or compounds thereof.

19. A gas deposition reactor as claimed in claim 1, wherein the first chamber is a pressure chamber containing low pressure, over pressure or substantially normal air pressure.

20. A gas deposition reactor as claimed in claim 1, wherein the second chamber is a reaction chamber in which the surface of a substrate is subjected to alternate surface reactions of starting materials.
